(19) United States
(12) Patent Application Publication
(10) Pub. No.: US 2020/0006210 A1
(43) Pub. Date: Jan. 2, 2020

(54) CHIP PACKAGE AND METHOD OF MANUFACTURING

(71) Applicant: Intel Corporation, Santa Clara, CA (US)

(72) Inventors: Cheng Xu, Chandler, AZ (US); Kyu Oh Lee, Chandler, AZ (US); Junnan Zhao, Gilbert, AZ (US); Rahul Jain, Gilbert, AZ (US); Ji Yong Park, Chandler, AZ (US)

(21) Appl. No.: 16/019,807

(22) Filed: Jun. 27, 2018

(51) Int. Cl. H01L 23/498; H01L 21/48

(52) U.S. Cl. CPC H01L 23/49822; H01L 23/49838; H01L 24/17; H01L 21/4857; H01L 21/486

(57) ABSTRACT

A chip package that includes a die coupled to a package substrate. The substrate includes a first ground layer and a dielectric material engaging the first ground layer. A solder resist layer engages the dielectric material and a routing layer is disposed at least partially within the solder resist layer. A second ground layer engages the solder resist layer.

### TECHNICAL FIELD

This document pertains generally, but not by way of limitation, to manufacturing electronic devices. More specifically, this document pertains to providing an improved chip package.

### BACKGROUND

Manufacturing components for electronic devices involves rigorous manufacturing processes that involve manufacturing to ensure quality performance, including signal strength and clarity provided by the electronic components. Such electronic components include mother boards, integrated circuits (ICs), chips, memory devices, modern processors, such as a central processing unit (CPU), a graphics processing unit (GPU), advanced processing unit (APU), or combinations thereof, and the like.

When chip packages for electronic components are manufactured, numerous electrical and mechanical characteristics are considered to create a viable product. Characteristics include, but are not limited to, physical damage, mechanical vibrations, thermal properties, electrical properties such as electric and magnetic fields, electrostatic discharge, package form and size, product loading, power delivery, signal integrity, and the like. These characteristics may be improved by not only improving individual components, but also by improving manufacturing processes of an electronic component or chip package.

In particular, there is a desire to reduce the size, and particularly the thickness of these electronic components and chip packages to provide design flexibility, reduce cost, and provide other advantages. However, such size reductions can result in detriment to other characteristics.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 is a side schematic view of a chip package in accordance with an example embodiment.

FIG. 2 is a top schematic view of a chip package in accordance with an example embodiment.

FIG. 3 is a side schematic view of a chip package during manufacturing in accordance with an example embodiment.

FIG. 4 is a side schematic view of a chip package during manufacturing in accordance with an example embodiment.

FIG. 5 is a side schematic view of a chip package during manufacturing in accordance with an example embodiment.

FIG. 6 is a side schematic view of a chip package during manufacturing in accordance with an example embodiment.

FIG. 7 is a block flow diagram of example devices in accordance with an example embodiment in accordance with an example embodiment.

### DETAILED DESCRIPTION

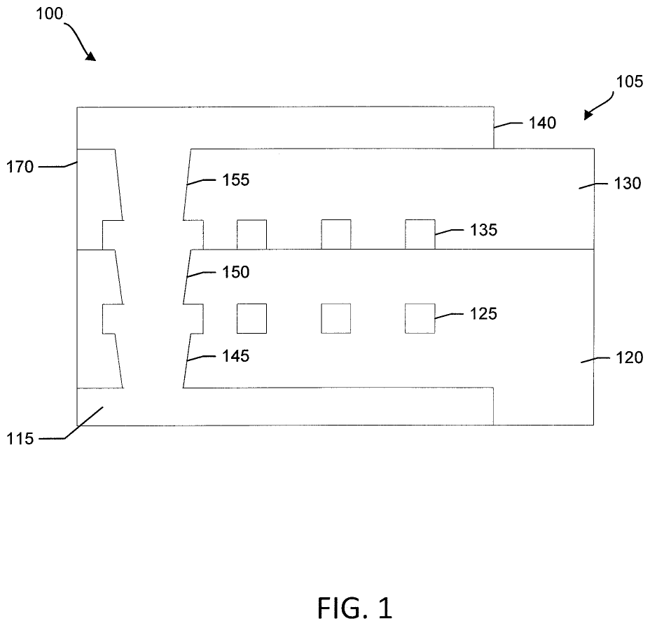

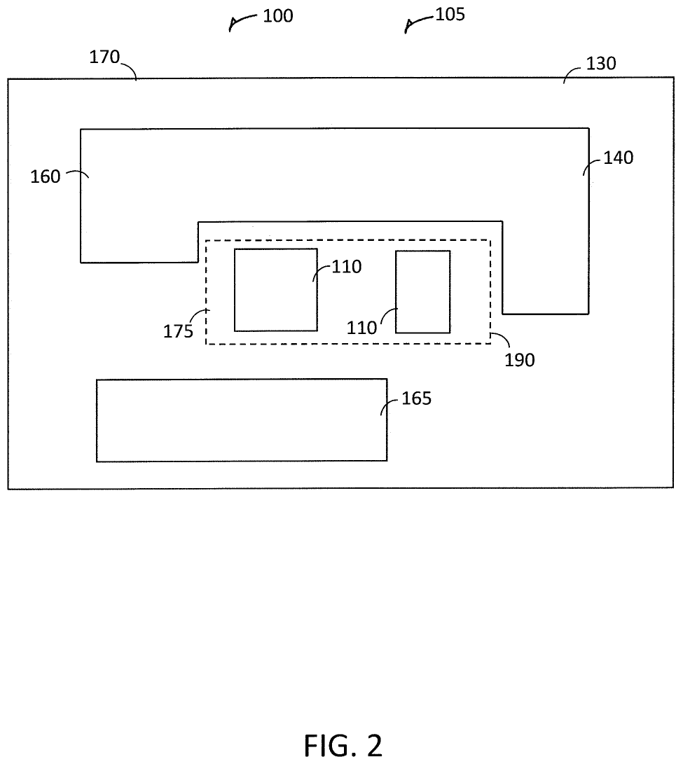

FIGS. 1-2 illustrate a chip package 100. The chip package 100 may be, or part of an integrated circuit (ICs), chip, memory device, modern processor, such as a central processing unit (CPU), a graphics processing unit (GPU), advanced processing unit (APU), or combinations thereof, and the like. The chip package 100 includes a substrate 105 coupled to at least one die 110. The substrate 105 includes a first ground layer 115, or plane, a dielectric material 120, a first routing layer 125, solder resist layer 130, second routing layer 135, a conductive layer that is a second ground layer 140, first via 145, second via 150, and third via 155. While illustrated as a substrate 105 with two ground layers 115, 140 and two routing layers 125, 135, a plurality of additional ground layers and routing layers may be disposed within the dielectric material 120 with an additional ground layer provided for each additional routing layer. In such examples, the second routing layer 135 and second ground layer 140 are considered a solder resist routing layer and a solder resist ground layer that represent the uppermost layers of the chip package 100. Similarly, in one example, the dielectric material 120 may be formed in numerous layers with each layer being composed of the same material.

The first ground layer 115 extends within and engages the dielectric material 120 and is coupled to the first via 145 that extends vertically from the first ground layer 115 to the first routing layer 125. The first routing layer 125 includes routing (also considered transmission lines) disposed through the dielectric material 120 for transmitting signals. The routing or transmission lines may include traces, planes, or pads. The routing layer is spaced from, but adjacent to the first ground layer 115 such that the first ground layer 115 reduces signal loss of the first routing layer 125. The second routing layer 135 engages the dielectric material 120 and is disposed at least partially within the solder resist layer 130. The second via 150 meanwhile extends vertically from the first routing layer 125 through the dielectric material 120 to the second routing layer 135 at the solder resist layer 130.

The solder resist layer 130 engages the dielectric material 120 and second routing layer 135. Specifically, the second routing layer 135 is at least partially disposed within the solder resist layer 130. The solder resist layer 130 is made from a material having different properties than the dielectric material 120. To this end, in one example, the solder resist layer 130 is laminated on the dielectric material 120 and openings are disposed therein using a lithography technique. Also extending through the solder resist layer 130 and engaging the second via 150 is the third via 155 that extends to the second ground layer 140 disposed on the solder resist layer 130. In this manner, the second ground layer 140 is electrically connected to the first ground layer by the vertically aligned vias 145, 150, 155.

As illustrated in FIG. 2, the second ground layer 140 engages and is deposited on the solder resist layer 130 and in one example includes a first ground portion, or section 160 and a second ground portion, or section 165 that are physically separated from one another. The first and second ground portions 160, 165 extend around a periphery 170 of the solder resist layer 130 and surround a controlled collapse chip connection (C4) area 175 of the solder resist layer 130 that is generally centrally located on the solder resist layer 130. The C4 area 175 includes one or more C4 structures formed at least partially within the solder resist layer 130. In one example, the C4 area 175 includes dies 110.

In order for the second ground layer 140 to reduce signal loss in the second routing layer 135, the first and second ground portions 160, 165 only need to cover, or be adjacent to, the routing of the second routing layer 135 that are disposed outside of a periphery 190 of the C4 area 175. Thus, because I/O routing is typically outside the C4 area 175 and adjacent the periphery of the chip package 100, the first and second ground portions 160, 165 may be located outside of the C4 area 175 and still function as a ground that reduces signal noise of the transmission lines of the adjacent second routing layer 135. Therefore, the second ground layer 140 is able to be deposited on the solder resist layer 130, eliminating a layer of the chip package 100 to reduce Z-height of the chip package 100 without effecting the performance of the chip package 100. Additionally, in one example, the second ground layer 140 may also be at least partially used as a conductive layer for electrical connection, thermal transport, power delivery, and the like.

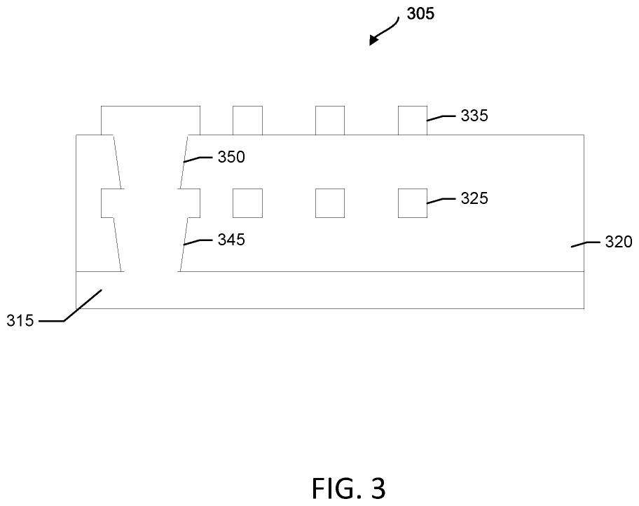

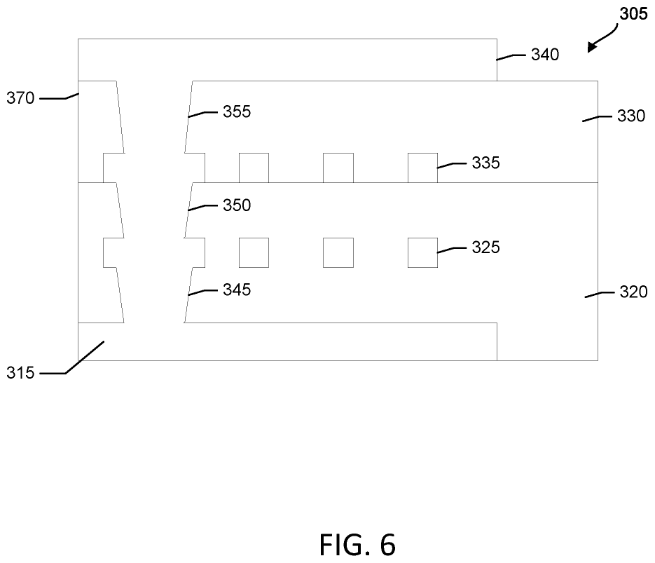

FIGS. 3-6 illustrate manufacturing steps in forming a substrate 305 for a chip package In one example the substrate 305 is the substrate 105 of FIGS. 1-2. In another example to form the chip package the substrate 305 is formed directly on a die, or dies, whereas in another example the substrate 305 is formed first, and a die, or dies, are attached thereafter. The substrate 305 when formed, similar to the substrate 105 of FIGS. 1 and 2, includes a first ground layer 315, or plane, a dielectric material 320, a first routing layer 325, solder resist layer 330, second routing layer 335, a conductive layer that is a second ground layer 340, first via 345, second via 350, and third via 355.

In an initial step, as illustrated in FIG. 3, the first ground layer 315, dielectric material 320, first routing layer 325, and second routing layer 335 are formed. This also includes the forming of first and second via 345, 350 that vertically stack on one another to provide an electrical connection. In an example, the dielectric material 320 is manufactured in layers, with a first dielectric layer including the first ground layer 315 and first via 345, another dielectric layer including the first routing layer 325, and yet another dielectric layer including the second via 350. In one example, the first ground layer 315, dielectric material 320, first routing layer 325, second routing layer 335, and via 345, 350 are formed using an additive process. In another example, the first ground layer 315, dielectric material 320, first routing layer 325, second routing layer 335, and via 345, 350 are formed using a subtractive process. While only a first ground layer 315, first routing layer 325, second routing layer 335, and via 345, 350 are illustrated engaging the dielectric material 320, additional ground layers, routing layers, and via may be added depending on the desired amount of routing and ground layers. In such examples, the number of ground layers formed will be one less than the number of routing layers.

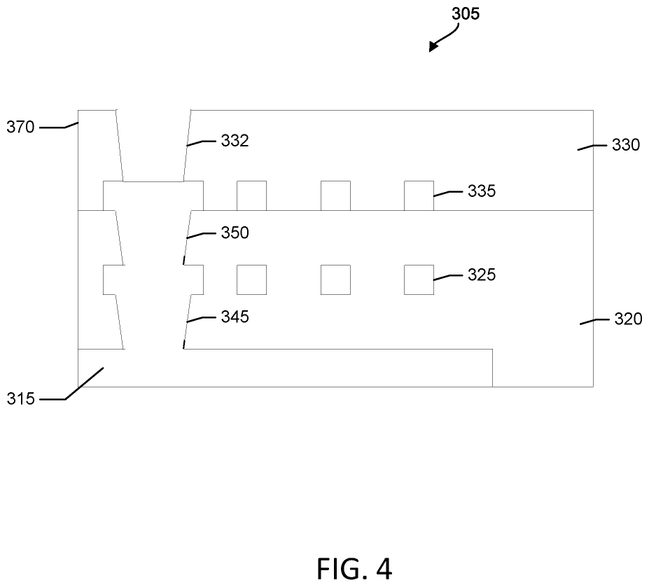

As illustrated in FIG. 4, next, a solder resist layer 330 is applied to and engages the dielectric material 320. Additionally, solder resist openings 332 are formed within the solder resist layer 330. In one example the solder resist layer 330 is laminated and a lithography method is utilized to provide the solder resist openings 332 located at desired locations. This includes adjacent the second via 350 and in the C4 area. In one example, from a top view, the C4 area is centrally located in the solder resist layer 330 (as illustrated in FIG. 2). In another example, a solder resist opening 332 is formed in an area where routing of the second routing layer 335 is not located adjacent, or underneath, the opening 332.

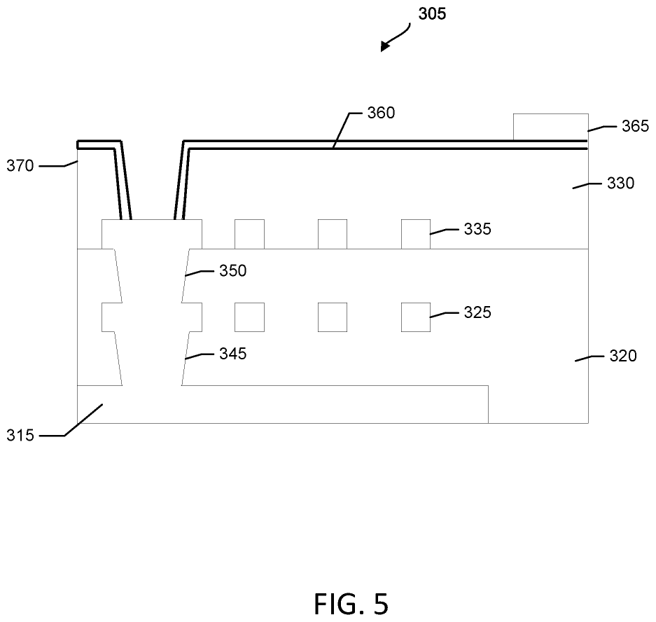

As illustrated in FIG. 5, after the solder resist layer 330 is formed, including forming of the solder resist openings 332, electroless copper (Cu) 360 is deposited on the solder resist layer 330. Electroless copper is copper having a composition such that the copper is deposited and coupled to the solder resist layer 330 without the use of electricity. Next, a dry film resist (DFR) 365 is applied and laminated to the solder resist layer 330 using a lithography process. The DFR 365 in one example is located in the C4 area and is applied in the solder resist opening 332 previously formed. Specifically, the DFR 365 is only opened to cover an area with I/O routing on the layer underneath or adjacent the solder resist layer 330. In this manner, the C4 area is covered by DFR 365 to prevent metal from being plated at the C4 area.

After application of the electroless Cu 360 and DFR 365, in one example, a conductive layer that in this example is a second ground layer 340 is then formed on the solder resist layer 330 through electroplating. While the conductive layer of this example functions as a ground layer 340, the conductive layer may also be utilized for electrical connection, thermal transport, power delivery, and the like. Not only is electroplating inexpensive compared to other manufacturing techniques, electroplating allows for a greater throughput than other techniques resulting in up to 30 um of metal to be deposited. In examples, the deposited metal may include copper, tin, gold, palladium, nickel, or an alloy or the like that may be electroplated. In another example the second ground layer is comprised of multiple layers of different materials including at least two of copper, tin, gold, palladium, nickel, or an alloy or the like that may be electroplated. While electroplating is described in one example, in other examples other techniques such as sputtering may be used to apply the second ground layer 340 to the solder resist layer 330. During the process of depositing the second ground layer 340 onto the solder resist layer 330 the third via 355 is also formed.

After the second ground layer 340 is completed, the remaining electroless Cu 360 and DFR 365 is removed. In one example the DFR 365 is stripped while flash etch is applied to remove the electroless Cu 360. After this, the solder resist opening for the C4 area is exposed such that dies may be received. Because the solder resist opening for the C4 area needs to be provided for the dies, by forming the second ground layer 340 during this step the solder resist openings are on the same level as the second ground layer 340. Therefore, by forming the second ground layer 340 together with the solder resist opening for the C4 area, instead of forming the second ground layer 340 within or engaging the dielectric material 320 or within a dielectric layer, a layer of material is eliminated, reducing Z-height of the chip package without an additional manufacturing step. Additionally, the second ground layer 340 is deposited only adjacent, or over, transmission lines of the adjacent second routing layer 335 and not in the C4 area. Instead, the second ground layer 340 surrounds the C4 area, leaving the C4 area available for C4 structures such as dies, or other electronic components while still reducing signal loss in the adjacent second routing layer 335. Therefore, the reduced Z-height is provided without loss in performance of the chip package.

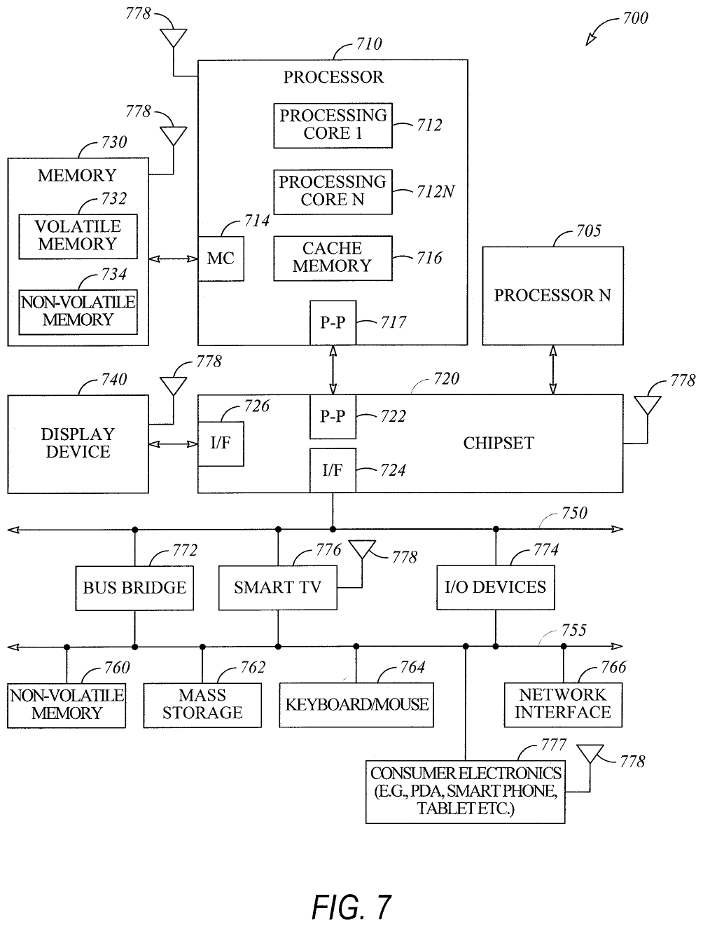

FIG. 7 illustrates a system level diagram, depicting an example of an electronic system including CPUs and processors, graphics devices, memories, and the like, any one of which may be an example of an electric component utilizing the chip package 100 of FIGS. 1-2 or a chip package formed using substrate 305 of FIGS. 3-6. FIG. 7 is included to show an example of a higher level device application for such example chip packages. In one embodiment, system 700 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device. In some embodiments, system 700 is a system on a chip (SOC) system.

In one embodiment, processor 710 has one or more processor cores 712 and 712N, where 712N represents the Nth processor core inside processor 710 where N is a positive integer. In one embodiment, system 700 includes multiple processors including 710 and 705, where processor 705 has logic similar or identical to the logic of processor 710. In some embodiments, processing core 712 includes, but is not limited to, pre-fetch logic to fetch instructions, decode logic to decode the instructions, execution logic to execute instructions and the like. In some embodiments, processor 710 has a cache memory 716 to cache instructions and/or data for system 700. Cache memory 716 may be organized into a hierarchal structure including one or more levels of cache memory.

In some embodiments, processor 710 includes a memory controller 714, which is operable to perform functions that enable the processor 710 to access and communicate with memory 730 that includes a volatile memory 732 and/or a non-volatile memory 734. In some embodiments, processor 710 is coupled with memory 730 and chipset 720. Processor 710 may also be coupled to a wireless antenna 778 to communicate with any device configured to transmit and/or receive wireless signals. In one embodiment, an interface for wireless antenna 778 operates in accordance with, but is not limited to, the IEEE 802.11 standard and its related family, Home Plug AV (HPAV), Ultra-Wide Band (UWB), Bluetooth, WiMax, or any form of wireless communication protocol.

In some embodiments, volatile memory 732 includes, but is not limited to, Synchronous Dynamic Random Access Memory (SDRAM), Dynamic Random Access Memory (DRAM), RAIVIBUS Dynamic Random Access Memory (RDRAM), and/or any other type of random access memory device. Non-volatile memory 734 includes, but is not limited to, flash memory, phase change memory (PCM), read-only memory (ROM), electrically erasable programmable read-only memory (EEPROM), or any other type of non-volatile memory device.

Memory 730 stores information and instructions to be executed by processor 710. In one embodiment, memory 730 may also store temporary variables or other intermediate information while processor 710 is executing instructions. In the illustrated embodiment, chipset 720 connects with processor 710 via Point-to-Point (PtP or P-P) interfaces 717 and 722. Chipset 720 enables processor 710 to connect to other elements in system 700. In some embodiments of the example system, interfaces 717 and 722 operate in accordance with a PtP communication protocol such as the Intel® QuickPath Interconnect (QPI) or the like. In other embodiments, a different interconnect may be used.

In some embodiments, chipset 720 is operable to communicate with processor 710, 705N, display device 740, and other devices, including a bus bridge 772, a smart TV 776, I/O devices 774, nonvolatile memory 760, a storage medium (such as one or more mass storage devices) 762, a keyboard/mouse 764, a network interface 766, and various forms of consumer electronics 777 (such as a PDA, smart phone, tablet etc.), etc. In one embodiment, chipset 720 couples with these devices through an interface 724. Chipset 720 may also be coupled to a wireless antenna 778 to communicate with any device configured to transmit and/or receive wireless signals.

Chipset 720 connects to display device 740 via interface 726. Display 740 may be, for example, a liquid crystal display (LCD), a light emitting diode (LED) array, an organic light emitting diode (OLED) array, or any other form of visual display device. In some embodiments of the example system, processor 710 and chipset 720 are merged into a single SOC. In addition, chipset 720 connects to one or more buses 750 and 755 that interconnect various system elements, such as I/O devices 774, nonvolatile memory 760, storage medium 762, a keyboard/mouse 764, and network interface 766. Buses 750 and 755 may be interconnected together via a bus bridge 772.

In one embodiment, mass storage device 762 includes, but is not limited to, a solid state drive, a hard disk drive, a universal serial bus flash memory drive, or any other form of computer data storage medium. In one embodiment, network interface 766 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra-Wide Band (UWB), Bluetooth, WiMax, or any form of wireless communication protocol.

While the modules shown in FIG. 7 are depicted as separate blocks within the system 700, the functions performed by some of these blocks may be integrated within a single semiconductor circuit or may be implemented using two or more separate integrated circuits. For example, although cache memory 716 is depicted as a separate block within processor 710, cache memory 716 (or selected aspects of 716) can be incorporated into processor core 712.

### VARIOUS NOTES & EXAMPLES

Example 1 is a chip package comprising: a die coupled to a package substrate, the package substrate including; a first ground layer; a dielectric material engaging the first ground layer; a solder resist layer engaging the dielectric material; a routing layer disposed at least partially within the solder resist layer; a conductive layer engaging the solder resist layer.

In Example 2, the subject matter of Example 1 optionally includes wherein the conductive layer is a second ground layer that is coupled to the first ground layer through one or more vias.

In Example 3, the subject matter of any one or more of Examples 1-2 optionally include wherein the conductive layer only covers selected regions of the solder resist layer.

In Example 4, the subject matter of Example 3 optionally includes wherein the conductive layer comprises one of copper, tin, or nickel.

In Example 5, the subject matter of any one or more of Examples 1-4 optionally include wherein the routing layer is one of multiple routing layers located between the first ground layer and the second ground layer.

In Example 6, the subject matter of any one or more of Examples 1-5 optionally include structures formed at least partially within the solder resist layer.

In Example 7, the subject matter of Example 6 optionally includes area of the solder resist layer.

In Example 8, the subject matter of Example 7 optionally includes area.

Example 9 is a chip package comprising: a die coupled to a package substrate, the package substrate including; a first ground layer; a dielectric material engaging the first ground layer; a solder resist layer engaging the dielectric material and including a controlled collapse chip connection (C4) area, the C4 area including one or more C4 structures formed at least partially within the solder resist layer; a routing layer disposed at least partially within the solder resist layer; a second ground layer engaging the solder resist layer adjacent the routing layer and including one or more sections surrounding the C4 area.

In Example 10, the subject matter of Example 9 optionally includes area is centrally located on the solder resist layer.

In Example 11, the subject matter of any one or more of Examples 9-10 optionally include wherein the second ground layer is electrically connected to one or more vias that pass through the solder resist layer.

In Example 12, the subject matter of Example 11 optionally includes wherein the first ground layer includes one or more vias that extent through at least a portion of the dielectric material.

In Example 13, the subject matter of Example 12 optionally includes wherein the first ground layer is coupled to the second ground layer through a stack of one or more vertically aligned vias.

In Example 14, the subject matter of any one or more of Examples 9-13 optionally include wherein the routing layer is one of multiple routing layers located between the first ground layer and the second ground layer.

In Example 15, the subject matter of any one or more of Examples 7-14 optionally include wherein the one or more section are physically separate from one another.

Example 16 is a method of manufacturing a chip package, comprising: forming a die coupled to a substrate, wherein the substrate is formed by: applying a dielectric material onto a first ground layer; applying a solder resist onto the dielectric material to form a solder resist layer; masking and selectively exposing the solder resist to pattern a second ground layer and a number of C4 structures concurrently; and applying the second ground layer onto the solder resist layer.

In Example 17, the subject matter of Example 16 optionally includes wherein applying the second ground layer to the solder resist layer comprises electroplating multiple, physically separate ground portions on the solder resist layer.

In Example 18, the subject matter of Example 17 optionally includes wherein applying the solder resist onto the dielectric material to form the solder resist layer comprises laminating the solder resist before electroplating the multiple, physically separate ground portions on the solder resist layer.

In Example 19, the subject matter of any one or more of Examples 17-18 optionally include) area of the solder resist layer with dry film resist before electroplating the multiple, physically separate ground portions on the solder resist layer.

In Example 20, the subject matter of any one or more of Examples 17-19 optionally include depositing electroless copper on the solder resist layer before electroplating the multiple, physically separate ground portions on the solder resist layer.

Each of these non-limiting examples may stand on its own, or may be combined in various permutations or combinations with one or more of the other examples.

The above detailed description includes references to the accompanying drawings, which form a part of the detailed description. The drawings show, by way of illustration, specific embodiments in which the invention may be practiced. These embodiments are also referred to herein as “examples.” Such examples may include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein may be machine or computer-implemented at least in part. Some examples may include a computer-readable medium or machine-readable medium encoded with instructions operable to configure an electronic device to perform methods as described in the above examples. An implementation of such methods may include code, such as microcode, assembly language code, a higher-level language code, or the like. Such code may include computer readable instructions for performing various methods. The code may form portions of computer program products. Further, in an example, the code may be tangibly stored on one or more volatile, non-transitory, or non-volatile tangible computer-readable media, such as during execution or at other times. Examples of these tangible computer-readable media may include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments may be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments may be combined with each other in various combinations or permutations. The scope of the invention should be determined with reference to the appended claims, along with the full scope of equivalents to which such claims are entitled.

1. A chip package comprising:
a die coupled to a package substrate, the package substrate including;
a first ground layer;
a dielectric material engaging the first ground layer;
a solder resist layer engaging the dielectric material;
a routing layer disposed at least partially within the solder resist layer;
an elecroplated conductive layer engaging the solder resist layer.

2. The chip package of claim 1, wherein the conductive layer is a second ground layer that is coupled to the first ground layer through one or more vias.

3. The chip package of claim 1, wherein the conductive layer only covers selected regions of the solder resist layer.

4. The chip package of claim 3, wherein the conductive layer comprises one of copper, tin, gold, palladium, nickel, or an alloy.

5. The chip package of claim 1, wherein the routing layer is one of multiple routing layers located between the first ground layer and the conductive layer.

6. The chip package of claim 1, wherein the solder resist layer includes a controlled collapse chip connection (C4) area including one or more C4 structures formed at least partially within the solder resist layer.

7. The chip package of claim 6, wherein the conductive layer engages the solder resist layer outside the C4 area of the solder resist layer.

8. The chip package of claim 7, wherein the conductive layer includes multiple, physically separate portions that are located over routing layer regions and not over the C4 area.

9. A chip package comprising:
a die coupled to a package substrate, the package substrate including;
a first ground layer;
a dielectric material engaging the first ground layer;
a solder resist layer engaging the dielectric material and including a controlled collapse chip connection (C4) area, the C4 area including one or more C4 structures formed at least partially within the solder resist layer;
a routing layer disposed at least partially within the solder resist layer;
an elecroplated conductive layer engaging the solder resist layer adjacent the routing layer and including one or more sections surrounding the C4 area.

10. The chip package of claim 9, wherein the C4 area is centrally located on the solder resist layer.

11. The chip package of claim 9, wherein the conductive layer is a second ground layer that is electrically connected to one or more vias that pass through the solder resist layer.

12. The chip package of claim 11, wherein the first ground layer includes one or more vias that extent through at least a portion of the dielectric material.

13. The chip package of claim 12, wherein the first ground layer is coupled to the second ground layer through a stack of one or more vertically aligned vias.

14. The chip package of claim 9, wherein the routing layer is one of multiple routing layers located between the first ground layer and the conductive layer.

15. The chip package of claim 9, wherein the one or more sections are physically separate from one another.

16.-20. (canceled)
